(19) United States
(12) Patent Application Publication
(10) Pub. No.: US 2001/0040300 A1
(43) Pub. Date: Nov. 15, 2001

(54) SEMICONDUCTOR PACKAGE WITH HEAT DISSIPATION OPENING

(76) Inventors: CHIEN-PING HUANG, HSINCHU (TW); CHENG-YUAN LAI, TAICHUNG (TW)

Correspondence Address: Dike Bronstein Roberts & Cushman, Intellectual Property Practice Group, Edwards & Angell, PO Box 9169, Boston, MA, 02209, US

(21) Appl. No.: 09/360,084

(22) Filed: Jul. 23, 1999

(30) Foreign Application Priority Data
Jul. 24, 1998 (TW) 87112087

(51) Int. Cl. H01L 23/28

(52) U.S. Cl. 257/787

(57) ABSTRACT

A semiconductor package having a lead frame is provided in which the lead frame has a plurality of leads and a die pad for mounting a semiconductor die. The die pad is formed with at least one opening for exposing a portion of the surface of the semiconductor die. An encapsulant is formed to enclose the semiconductor die, portions of the leads and a portion of the die pad, while having a surface of the die pad to expose the form of the encapsulant. As a surface of the die pad is exposed to the exterior of the encapsulant, the opening formed on the die pad provides a thermal conduction path from the semiconductor die to the ambient, thereby enhancing the heat dissipation property of the semiconductor package.

### BACKGROUND OF THE INVENTION

The present invention relates to semiconductor packages, and more particularly to a semiconductor package that employs a lead frame having a die pad for bearing a semiconductor die.

### DESCRIPTION OF THE PRIOR ART

Normally, in conventional semiconductor packages, a heat sink or a heat slug is used to directly contact or indirectly contact with the semiconductor chip for effectively dissipating heat generated from the semiconductor chip in operating to the atmosphere. A semiconductor package having a heat slug has been disclosed in U.S. Pat. No. 5,381,042 to increase the efficiency of heat dissipation. As shown in FIG. 5, in the semiconductor package disclosed in U.S. Pat. No. 5,381,042, a surface of the heat slug 400 is directly exposed to the exterior of the solid encapsulant 601 for effectively dissipating heat generated from the semiconductor die 520 to the atmosphere via a thermal conduction route consisted of the silver paste 600, die pad 522, and heat slug 400.

However, the thickness of the semiconductor package is increased due to the incorporation of the heat slug 400. Thus, nowadays, for thin type semiconductor packages with thickness of less than 1.4 mm or 1.0 mm, such as TSOP (Thin Small Outline Package), SSOP (Shrink Small Outline Package), and TQFP (Thin Quad Flat Package), to incorporate a heat slug into such a thin type semiconductor package is hard to be achieved the thermal conductive path for dissipating heat generated by the semiconductor die 520 to the atmosphere via silver paste, the die pad 522, and the heat sink 400 is so long that the efficiency of heat dissipation is reduced. And, the incorporation of the heat slug 400 into the semiconductor package increases the production cost and requires extra processes and equipment. Furthermore, the die pad 522 makes contact with the heat slug 400 and the semiconductor die 520 in a surface-to surface manner and the coefficients of thermal expansion (CTE) of the semiconductor die 520, die pad 522, and heat slug 400 are different from each other, so that the heating and cooling treatments in the packaging process tend to result in significant thermal stress thereon, causing delamination to incur on the interface between the semiconductor die 520 and die pad 522. Meanwhile, there tends to exist gaps between the heat slug 400 and the encapsulant 601 and between the heat slug 400 and the die pad 522 which provide moisture in the atmosphere with a penetration path into the package. As a result, in the SMT process, the penetrating moisture would be vaporized and expanded when heated and thereby “popcorn cracks” occur in the package body. Besides, in the molding process, the molding compound may flash on the exposed surface of the heat slug whereby the efficiency of heat dissipation and the outlook of the package are adversely affected.

A semiconductor package having a downset exposed lead frame has been disclosed by U.S. Pat. No. 5,594,734 for solving the aforesaid problems. In the semiconductor package of U.S. Pat. No. 5,593,234, as shown in FIG. 6, there is a downset between the die pad 720, which is uniformly formed with the lead frame 700, and the leads 710 to make a surface of the die pad 720 be exposed the outside of the package and directly contact with conventional heat dissipation devices, such as heat sink, thermal dissipating clip, or heat conductive vias of the PCB, for effectively dissipating the heat generated by the chip to the atmosphere through the heat dissipation path along the chip, the silver paste 900, the die pad 720, and the hear dissipation device without using the heat slug.

Such a semiconductor package without the use of a heat slug can not only fit the requirements for a thin type semiconductor device, but also eliminate cost for using the heat slug.

However, the aforesaid semiconductor package without the use of a heat slug still has problems. That is, since the chip 800 makes constant with the die pad 720 in a surface-to-surface manner delamination of the chip 800 from the die pad 720 still occurs due to thermal stress caused by heating in the packaging process. Furthermore, despite that the semiconductor package is made without the incorporation of a heat slug, the thermal conductive path for dissipating hot generated by the chip 800 to the die pad 720 through the silver paste is still long.

### SUMMARY OF THE INVENTION

Accordingly, it is an object of the present invention to provide a semiconductor package having a heat dissipation opening to be used in the thin-type semiconductor devices.

Another object of the present invention is to provide a semiconductor package with a heat dissipation opening in which thermal conductivity is improved without the incorporating of a heat sink.

Still another object of the present invention is to provide a semiconductor package having a heat dissipation opening which avoids delamination of a chip from a die pad on which the chip is mounted.

Still another object of the present invention is to provide a semiconductor package having a heat dissipation opening in which the efficiency of heat dissipation is improved.

Still another purpose of the present invention is to provide a semiconductor package having a heat dissipation opening in which an additional heat slug can be directly connected to the chip for directly dissipating heat generated by the chip to the atmosphere through the heat slug.

The above and other objects of the present invention are achieved by a semiconductor package including a semiconductor chip having a first surface and a second surface, a plurality of leads for electrically connecting with the first surface of the semiconductor chip, a die pad having a first surface to which the second surface to the chip is adhered and at least one opening covered by the semiconductor chip on one end of the opening, and an encapsulant encapsulating the semiconductor chip, the die pad, and portions of the leads in a manner that the second surface of the semiconductor chip is directly exposed to the exterior of the encapsulant, allowing a portion of the second surface or the semiconductor chip to be exposed to the atmosphere via the opening. Being not encapsulated by the encapsulant, the opening of the die pad provides the heat generated by the semiconductor chip with a thermal conductive path directly to the atmosphere. In addition as only a portion of the second surface of the semiconductor chip is adhered to the die pad, the delamination of the semiconductor chip from the die pad can be effectively improved. Besides, the opening of the die pad provides a direct contact of the second surface of the semiconductor chip to an external heat dissipator, eliminating the use of an internal heat sink.

The above and other objects, features and advantages of the present invention will be apparent from the following description of preferred embodiments of the invention with reference to the accompanying drawings.

### BRIEF DESCRIPTION OF THE DRAWINGS

The above and other objects, features and other advantage of the present invention will be more clearly understood from the following detailed description taken in conjunction with the accompanying drawings, in which:

FIG. 1 is a sectional view which illustrates the semiconductor package in accordance with a first embodiment of the present invention;

FIG. 2 is a sectional view which illustrates the semiconductor package in accordance with a second embodiment of the present invention;

FIG. 3A to FIG. 3F are top views of other types of die pads suitable for use in the semiconductor packages of the present invention;

FIG. 4 is a section view which illustrates the semiconductor package in accordance with a third embodiment of the present invention;

FIG. 5 is a sectional view which illustrates a conventional semiconductor package with a heat sink; and

FIG. 6 is a sectional view of another conventional semiconductor package.

### DETAILED DESCRIPTION OF THE PREFERRED EMBODIMENTS

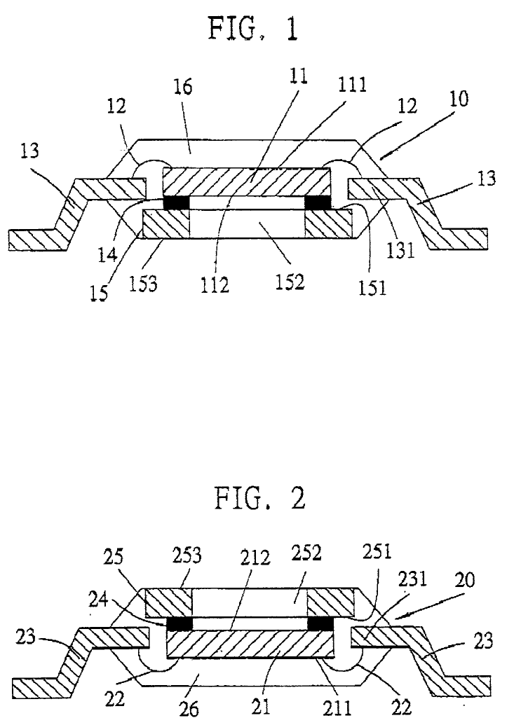

Referring to FIG. 1, there is shown a first embodiment of a TQFP semiconductor package according to the present invention. As shown in FIG. 1, in semiconductor package 10, a semiconductor chip 11 has a first surface 111 electrically connected to inner ends 131 of a plurality of leads 13 through bonding wires 12 and a second surface 112 opposing the first surface 111, adhered to a first surface 151 of a die pad 15 by an adhesive material 14 with thermal conductive properly such as silver paste. The die pad 15 has a first surface 151 and a second surface 153 opposite to the first surface 151 and is formed with an opening 152 in the center. The opening 152 has one end completely covered or sealed by the semiconductor chip 11 when attached to the first surface 151 of the die pad 15. The semiconductor 11, the die pad 15, and the inner ends 131 of the leads 13 are then encapsulated by an encapsulant 16 formed by a molding compound by transfer molding or similar moods, allowing the second surface 153 of the die pad 15 to be exposed to the outside of the encapsulant 16. Thus, this renders the portion of the second surface 112 of the chip 11 covering the opening 152 of the die pad 15 to be directly exposed to the atmosphere via the opening 152 of the die pad 15, so that the heat generated by the chip 11 can be directly dissipated to the atmosphere via the second surface 112 and the opening 152 of the die pad 15. As a result, the package 10 of the first embodiment of the present invention has advantages that the heat generated by the chip is provided with a direct thermal conductive path to the atmosphere, enhancing the them conductivity of the semiconductor package 10 and that the delamination of the semiconductor chip 11 from the die pad 15 is eliminated as only a small portion of the semiconductor chip 11 is adhered to the die pad 15.

In the present embodiment, the die pad 15 is downset to a plane below and horizontal to a plane of the leads 13 in order to expose the second surface 153 of the die pad 15 to the exterior of the encapsulant 16 after the transfer molding process is completed.

FIG. 2 shows a cross sectional view of a semiconductor package according to a second embodiment of the present invention. In FIG. 2, a semiconductor package 20 is illustrated with a structure essentially the same as that mentioned in the first embodiment, except that the semiconductor chip is positioned below the die pad.

As shown in FIG. 2, a die pad 25 has a first surface 251 adhered with a semiconductor chip 21 by adhesive material 4 and a second surface 253 opposing the first surface 251. The die pad 25 is also formed with an opening 252 in the center, allowing one end of the opening 252 to be covered or sealed by the semiconductor chip 21. The semiconductor chip 21 is formed with a first surface 211 for electrically connecting to inner ends 231 of leads 23 surrounding the semiconductor chip 21 by bonding wires 22 and a second surface 212 for attaching to the first surface 251 of the die pad 25, allowing a portion of which to be exposed to the atmosphere via the opening 252 of the die pad 25. By transfer molding, an encapsulant 26 is formed to encapsulate the semiconductor chip 21, die pad 25 and inner ends 231 of the leads 23 in a manner that the second surface 253 of the die pad 25 is exposed to the exterior of the encapsulant 26. Consequently, the heat generated by the semiconductor chip 21 can be dissipated directly to the atmosphere via the opening 252 of the die pad 25.

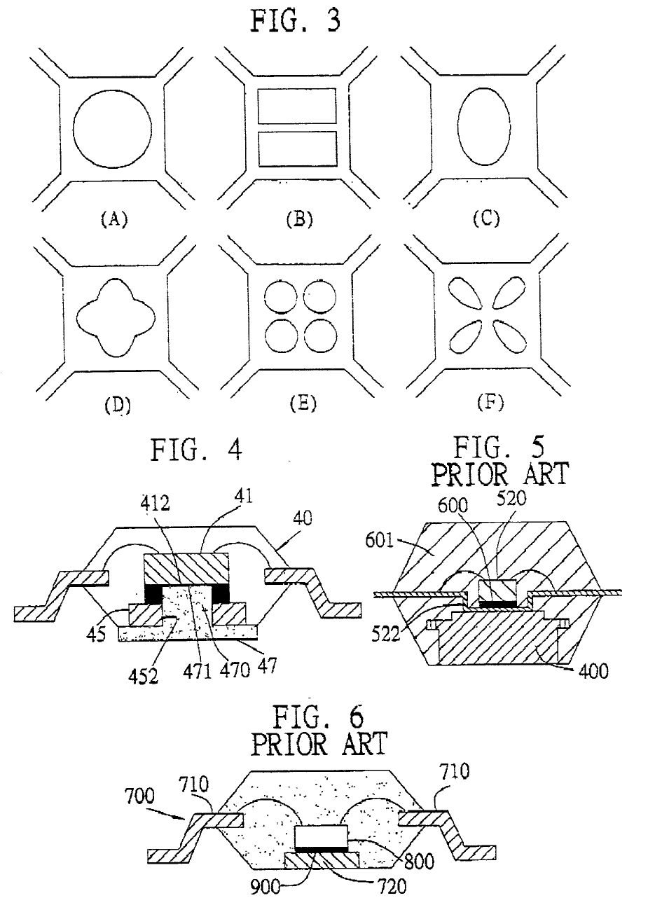

As shown from FIG. 3A to 3F, in variations of the die pad suitable for the present invention are illustrated, such as round shape, square shape, ellipsoidal shape, and multi-angular shape and the die pad can be formed with more than one opening.

Referring to FIG. 4 a semiconductor package 40 of a third embodiment according to the present invention has the same structure as that in the aforesaid first and second embodiments. However, a heat spreader 47 having a central protrusion 470 for engaging with the opening 452 of the die pad 45 is combined with the package 40. While the engagement of the central protrusion 470 of the heat spreader 47 with the opening 452 of the die pad 45 is completed, the top surface 471 of the central protrusion 470 is in direct contact with the second surface 412 of the semiconductor chip 41 whereby the heat generated by the chip 41 can be dissipated to the atmosphere through the heat slug 47. Besides, thermal conductive epoxy adhesive may be applied to the interface between the second surface 412 of the chip 41 and the upper surface 471 of the heat spreader 47.

As described above, the present invention provides a semiconductor package with improved heat dissipation. In the present invention, there is no external or internal heat dissipation devices, such as heat dissipation plate, heat dissipation block, or thermal conductive tunnel, necessary to be combined with the package body so that the production cost and manufacturing steps are reduced. By forming at least one opening in the die pad, the heat generated by the chip can be directly dissipated to the atmosphere via the opening As only a portion of the chip is adhered to the dip pad, the delamination of the semiconductor chip from the die pad is effectively eliminated and the reliability of the semiconductor package is enhanced.

The present invention has been described hitherto with exemplary preferred embodiments. However, it is to be understood that the scope of the present invention need not be limited to the disclosed preferred embodiments. On the contrary, it is intended to cover various modifications and similar arrangements with the scope defined in the following appended claims. The scope of the claims should be accorded the broadest interpretation so as to encompass all such modifications and similar arrangements.

What is claimed as:

1. A semiconductor package comprising:
a semiconductor chip having a first surface and a second surface;
a plurality of leads having inner ends which are electrically connected with the first surface of the chip;
a die pad having a first race to which said second surface of the semiconductor chip is adhered, a second surface opposing the first surface of said die pad, and at least one opening formed through the first and second surfaces of said die pad, wherein one end of the opening is covered by the semiconductor chip, allowing a portion of the second surface of the semiconductor chip to be exposed to the opening of said die pad; and
an encapsulant encapsulating the semiconductor chip, the die pad except the second surface of the die pad, and the inner ends of the leads.

2. The semiconductor package according to claim 1, wherein the first surface of the chip is electrically connected to the inner ends of the leads by bonding wires.

3. The semiconductor package according to claim 1, wherein the semiconductor chip is adhered to the die pad by adhesive material.

4. The semiconductor package according to claim 3, wherein the adhesive material is of thermal conductive property.

5. The semiconductor package according to claim 4, wherein the adhesive material with thermal conductive property is silver paste.

6. The semiconductor package according to claim 1, wherein a heat dissipation device is further attached to the second surface of the semiconductor chip via the opening of the die pad.

7. The semiconductor package according to claim 1, wherein the opening is formed in a square, rectangular, circular ellipsoidal, or multi-angular shape.

8. The semiconductor package according to claim 1, wherein the die pad is downset to a plane below the plane of the leads.

9. A semiconductor package comprising:
a semiconductor chip having a first surface and a second surface;
a plurality of leads having inner ends which are electrically connected with the first surface of the semiconductor chip;
a die pad having a first surface for attaching the second surface of the semiconductor chip, a second surface opposing the first surface of the die pad, and at least one opening formed through the first and second surfaces of the die pad wherein one end of the opening is covered by the semiconductor package, allowing a portion of the second surface of the semiconductor chip to be exposed to the opening of the die pads and the die pad is downset to a plane below the plane of the leads; and
an encapsulant encapsulating the semiconductor chip, the die pad except the second surface thereof, and the inner ends of the leads.

10. The semiconductor package according to claim 9, wherein the first surface of the chip is electrically connected to the inner ends of the leads by bonding wires.

11. The semiconductor package according to claim 9, wherein the semiconductor chip is adhered to the die pad by an adhesive material.

12. The semiconductor package according to claim 11, wherein the adhesive material is of thermal property.

13. The semiconductor package according to claim 12, wherein the adhesive material with thermal conductive property is silver paste.

14. The semiconductor package according to claim 9, wherein a heat dissipation device is further attached to the second surface of the semiconductor chip via the opening of the die pad.

15. The semiconductor package according to claim 9, wherein the opening is formed in a square, rectangular, circular ellipsoidal, or multi-angular shape.
